(19) United States
(12) Patent Application Publication
(10) Pub. No.: US 2024/0402583 A1
(43) Pub. Date: Dec. 5, 2024

(54) PROJECTOR

(71) Applicant: SEIKO EPSON CORPORATION, Tokyo (JP)

(72) Inventors: Toshio MATSUMIYA, Matsumoto-shi (JP); Keita TSUKIOKA, Matsumoto-shi (JP); Yosuke NAKATA, Matsumoto-shi (JP); Nobuyuki OTSUKI, Matsumoto-shi (JP)

(73) Assignee: SEIKO EPSON CORPORATION, Tokyo (JP)

(21) Appl. No.: 18/678,248

(22) Filed: May 30, 2024

(30) Foreign Application Priority Data
May 31, 2023 (JP) 2023-090341

(51) Int. Cl. G03B 21/16; H05K 7/20

(52) U.S. Cl. CPC G03B 21/16; H05K 7/20136

(57) ABSTRACT

A projector includes an exterior housing having a first wall, an introduction port via which outside air is introduced as a cooling gas into the exterior housing, and a discharge port via which the cooling gas is discharged, a first cooling target disposed at the inner surface of the first wall, a cooling fan including an intake portion that sucks the cooling gas and a sending portion that sends the sucked cooling gas, a first flow path that cause the cooling gas to flow between the introduction port and the intake portion, and a second flow path that cause the cooling gas to flow between the sending portion and the discharge port. The first flow path is formed by a first surface of the first cooling target, and the second flow path is formed by a second surface different from the first surface in the first cooling target.

The present application is based on, and claims priority from JP Application Serial Number 2023-090341, filed May 31, 2023, the disclosure of which is hereby incorporated by reference herein in its entirety.

### BACKGROUND

### 1. Technical Field

The present disclosure relates to a projector.

### 2. Related Art

There is a known projector that includes a wireless communication apparatus that wirelessly communicates with an external device, such as a video output apparatus, and projects image light according to a video signal received from the external device (see JP-A-2021-157078, for example).

In the projector described in JP-A-2021-157078, the wireless communication apparatus is fixed to a flow path forming member provided in the exterior housing, and forms, along with the flow path forming member, a flow path through which a cooling gas flows. That is, one outer surface of the wireless communication apparatus is exposed to the interior of the flow path formed by the wireless communication apparatus and the flow path forming member. The cooling gas sent from a cooling fan flows through the flow path. The cooling gas thus flows along the aforementioned one outer surface of the wireless communication apparatus to cool the wireless communication apparatus.

JP-A-2021-157078 is an example of the related art.

In the projector described in JP-A-2021-157078, the cooling gas is caused to flow along one outer surface of the cooling target to cool the cooling target, as described above. Therefore, when the amount of heat generated by the cooling target is large, the effect of cooling the cooling target is not sufficient in some cases. In this case, to increase the ability of the cooling fan to cool the cooling target, it is conceivable, for example, to increase the size of the fan or increase the rotational speed of the cooling fan.

However, increasing the size of the fan also increases the size of the exterior housing, in which the fan is disposed, and in turn causes a problem of an increase in the size of the projector.

In addition, increasing the rotational speed of the cooling fan may cause problems, such as an increase in power consumption, an increase in the amount of heat generated by the power supply system, and an increase in noise generated by the cooling fan.

It has therefore been required to provide a configuration capable of increasing the efficiency at which the cooling target is cooled.

### SUMMARY

A projector according to an aspect of the present disclosure is a projector that projects image light, the projector including an exterior housing having a first wall, an introduction port via which outside air is introduced as a cooling gas into the exterior housing, and a discharge port via which the cooling gas having flowed through the interior of the exterior housing is discharged, a first cooling target disposed inside the exterior housing along an inner surface of the first wall, a cooling fan provided inside the exterior housing and including an intake portion that sucks the cooling gas and a sending portion that sends the sucked cooling gas, a first flow path that cause the cooling gas to flow between the introduction port and the intake portion, at least part of the first flow path being formed by a first surface of the first cooling target, and a second flow path that cause the cooling gas to flow between the sending portion and the discharge port, at least part of the second flow path being formed by a second surface different from the first surface in the first cooling target.

### BRIEF DESCRIPTION OF THE DRAWINGS

FIG. 1 is a perspective view showing a projector according to an embodiment.

FIG. 2 is a perspective view showing the projector according to the embodiment.

FIG. 3 is a perspective view showing the projector according to the embodiment with a fabric omitted.

FIG. 4 is a cross-sectional view showing the projector according to the embodiment.

FIG. 5 is a diagrammatic view showing the configuration of a light source apparatus according to the embodiment.

FIG. 6 is a perspective view showing a wireless communication apparatus and a first fan according to the embodiment.

FIG. 7 is a perspective view of the projector according to the embodiment with a lower case and a fabric unit removed.

FIG. 8 is a perspective view showing a speaker unit according to the embodiment.

FIG. 9 describes the flow of a cooling gas introduced into an exterior housing according to the embodiment.

FIG. 10 describes the flow of the cooling gas introduced into the exterior housing according to the embodiment.

FIG. 11 describes the flow of the cooling gas introduced into the exterior housing according to the embodiment.

FIG. 12 shows a second duct and the flow of the cooling gas through the second duct according to the embodiment.

### DESCRIPTION OF EMBODIMENTS

An embodiment of the present disclosure will be described below with reference to the drawings.

### Configuration of Projector

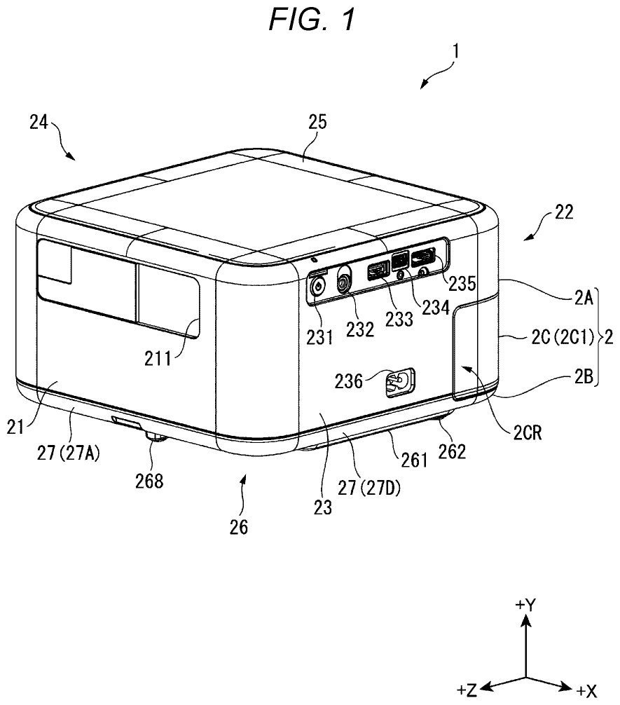

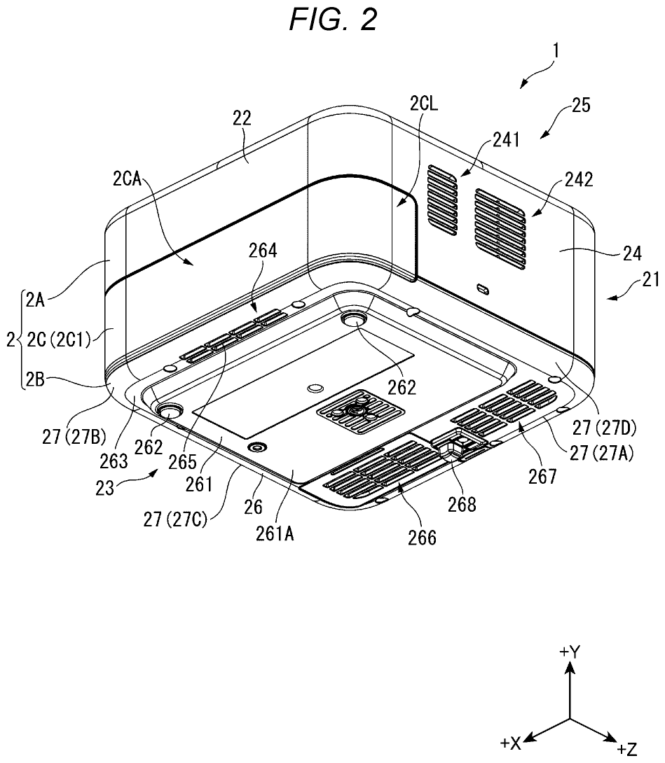

FIGS. 1 and 2 are perspective views showing a projector 1 according to the present embodiment. In detail, FIG. 1 is a perspective view showing the projector 1 viewed from the upper front side, and FIG. 2 is a perspective view showing the projector 1 viewed from the lower rear side.

The projector 1 according to the present embodiment projects image light according to image information onto a projection receiving surface. The projector 1 includes an exterior housing 2, as shown in FIGS. 1 and 2.

In the following description, three directions perpendicular to one another are called X, Y, and Z directions toward the positive ends thereof. The Y direction toward the positive end thereof is the direction that vertically extends upward from an installation surface at which the projector 1 is installed. When the projector 1 is viewed from the side facing the positive end of the Y direction, the Z direction toward the positive end thereof is the direction in which the projector 1 projects the image light.

Although not shown, the opposite direction of the X direction toward the positive end thereof is called the X direction toward the negative end thereof, the opposite direction of the Y direction toward the positive end thereof is called the Y direction toward the negative end thereof, and the opposite direction of the Z direction toward the positive end thereof is called the Z direction toward the negative end thereof. Although not shown, an axis along the X direction toward the positive end thereof is called an X-axis, an axis along the Y direction toward the positive end thereof is called a Y-axis, and an axis along the Z direction toward the positive end thereof is called a Z-axis.

### Configuration of Exterior Housing

The exterior housing 2 is a housing that constitutes the exterior of the projector 1, as shown in FIGS. 1 and 2. The exterior housing 2 includes an upper case 2A, which constitutes a portion facing the positive end of the Y direction, a lower case 2B, which constitutes a portion facing the negative end of the Y direction, and a fabric unit 2C, which constitutes a portion facing the negative end of the Z direction, a portion facing the positive end of the X direction, a portion facing the negative end of the X direction. The exterior housing 2 is formed in a substantially rectangular-box-like shape that is the combination of the upper case 2A, the lower case 2B, and the fabric unit 2C. The exterior housing 2 has a front surface 21, a rear surface 22, a right side surface 23, a left side surface 24, a top surface 25, a bottom surface 26, and an inclining surface 27.

The front surface 21 is formed by a portion of the upper case 2A that faces the negative end of the Y direction and a portion of the lower case 2B that faces the positive end of the Y direction. The rear surface 22, the right side surface 23, and the left side surface 24 are each formed by a portion of the upper case 2A that faces the negative end of the Y direction, a portion of the lower case 2B that faces the positive end of the Y direction, and the fabric unit 2C. The top surface 25 is formed by the upper case 2A, and the bottom surface 26 is formed by the lower case 2B.

### Configurations of Front Surface and Rear Surface

The front surface 21 shown in FIG. 1 and the rear surface 22 shown in FIG. 2 are surfaces opposite from each other along the Z-axis. In the present embodiment, the rear surface 22 corresponds to a first wall.

The front surface 21 is a side surface of the exterior housing 2 that faces the positive end of the Z direction, and is continuous with the bottom surface 26, as shown in FIG. 1. The front surface 21 is provided with a projection port 211, via which the image light to be projected onto the projection receiving surface passes.

The rear surface 22 is a side surface of the exterior housing 2 that faces the negative end of the Z direction, as shown in FIG. 2. The portion of the rear surface 22 that faces the negative end of the Y direction is formed by the fabric unit 2C, which covers a speaker unit 6, which will be described later, from the side facing the negative end of the Z direction.

### Configurations of Right Side Surface and Left Side Surface

The right side surface 23 shown in FIG. 1 and the left side surface 24 shown in FIG. 2 are surfaces opposite from each other along the X-axis.

The right side surface 23 is a side surface of the exterior housing 2 that faces the positive end of the X direction, as shown in FIG. 1. A power button 231, connection terminals 232 to 235, and an inlet 236 are provided at the right side surface 23.

The left side surface 24 is a side surface of the exterior housing 2 that faces the negative end of the X direction, as shown in FIG. 2. The left side surface 24 is provided with discharge ports 241 and 242, via which a cooling gas having flowed through the interior of the exterior housing 2 is discharged.

### Configuration of Fabric Unit

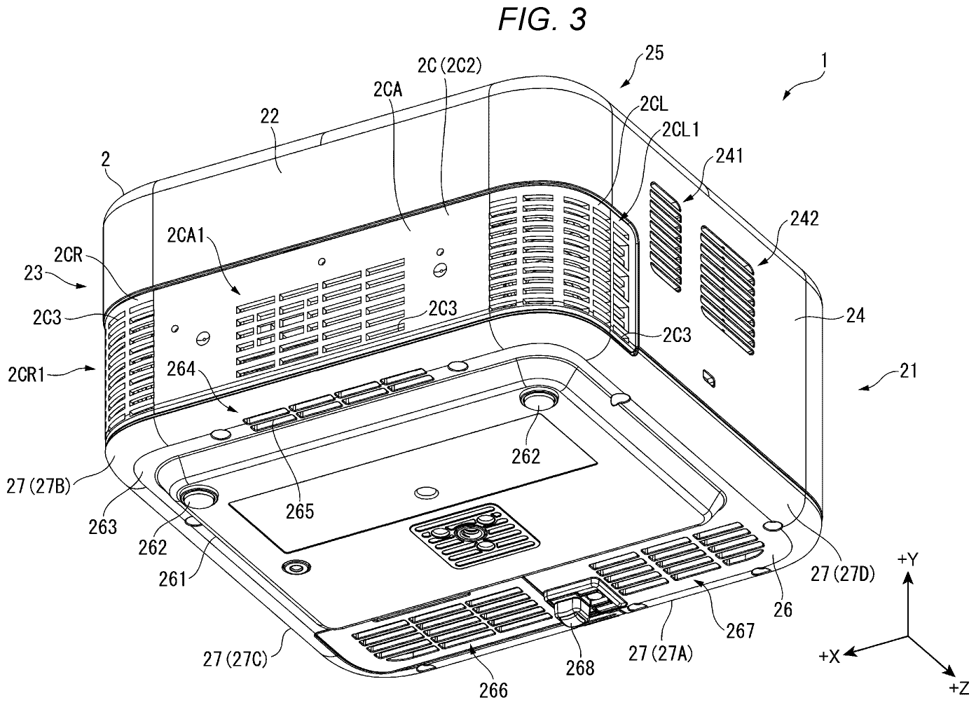

FIG. 3 is a perspective view of the projector 1 viewed from the side facing the negative end of the Z direction with a fabric 2C1, which constitutes the fabric unit 2C, omitted. In FIG. 3, reference characters are given only to some of a plurality of openings 2C3, which constitute communication ports 2CA1, right sound emission ports 2CR1, and left sound emission ports 2CL1.

The fabric unit 2C is disposed so as to extend across the rear surface 22 and to part of the right side surface 23 and the left side surface 24, as shown in FIGS. 1 and 2. The fabric unit 2C includes the fabric 201 formed of a net, as shown in FIGS. 1 and 2, and further includes a frame 2C2, which supports the fabric 2C1, as shown in FIG. 3.

The fabric 2C1 is provided at the outer surface of the frame 2C2 to cover the frame 2C2.

The frame 2C2 is formed in a substantially U shape when viewed from the side facing the positive end of the Y direction, as shown in FIG. 3. The frame 2C2 includes a rear surface part 2CA, which constitutes a portion of the rear surface 22 that faces the negative end of the Y direction, a right side surface part 2CR, which constitutes a portion of the right side surface 23 that faces the negative ends of the Y and Z directions, and a left side surface part 2CL, which constitutes a portion of the left side surface 24 that faces the negative ends of the Y and Z directions.

The rear surface part 2CA has the communication ports 2CA1, which cause the interior and the exterior of the exterior housing 2 to communicate with each other.

The communication ports 2CA1 are formed of a plurality of openings 2C3 arranged horizontally and vertically, and each of the openings is a sound emission port of a first sound emitter 62, which will be described later, and is also an introduction port via which the air outside the exterior housing 2 is introduced as the cooling gas into the exterior housing 2. That is, the exterior housing 2 has the communication ports 2CA1 corresponding to the plurality of introduction ports. The flow path resistance exerted on the cooling gas passing through the communication ports 2CA1 is greater than the flow path resistance exerted on the cooling gas passing through first intake ports 264 provided at the bottom surface 26, which will be described later.

The right side surface part 2CR has the right sound emission ports 2CR1, which serve as sound emission ports of a second sound emitter 63, which will be described later.

The left side surface part 2CL has the left sound emission ports 2CL1, which serve as sound emission ports of a second sound emitter 64, which will be described later.

The right sound emission ports 2CR1 and the left sound emission ports 2CL1 are each formed of a plurality of openings 2C3 arranged horizontally and vertically, and cause the interior and the exterior of the exterior housing 2 to communicate with each other, as the communication ports 2CA1 are. The flow path resistance exerted on the cooling gas flowing through the communication ports 2CA1, the flow path resistance exerted on the cooling gas flowing through the right sound emission ports 2CR1, and the flow path resistance exerted on the cooling gas flowing through the left sound emission ports 2CL1 are equal to one another.

### Configurations of Top Surface and Bottom Surface

The top surface 25 shown in FIG. 1 and the bottom surface 26 shown in FIG. 2 are surfaces opposite from each other along the Y-axis. The bottom surface 26 is a wall that is continuous with the rear surface 22 and intersects with the rear surface 22, and corresponds to a second wall.

The top surface 25 is a surface of the exterior housing 2 that faces the positive end of the Y direction, as shown in FIG. 1.

The bottom surface 26 is a surface of the exterior housing 2 that faces the negative end of the Y direction, as shown in FIG. 2. In other words, the bottom surface 26 is an opposing surface that opposes the installation surface at which the projector 1 is placed, and is a portion of the exterior housing 2 that is visible from the side facing the negative end of the Y direction.

The bottom surface 26 has a protrusion 261 and a step 263.

The protrusion 261 is a portion protruding toward the negative end of the Y direction and located substantially at the center of the bottom surface 26, and is formed in a substantially rectangular shape when viewed from the side facing the negative end of the Y direction. The protrusion 261 is provided with fixed legs 262.

The fixed legs 262 are provided at two corners of the protrusion 261 that face the negative end of the Z direction. The fixed legs 262 form one of contact portions in contact with the installation surface.

The step 263 is a portion of the bottom surface 26 that is not the protrusion 261, and is a noncontact portion that does not come into contact with the installation surface. Specifically, the step 263 is disposed at a position shifted toward the positive end of the Y direction from a surface 261A of the protrusion 261, at which the fixed legs 262 are provided, and is separate from the installation surface toward the positive end of the Y direction when the projector 1 is installed at the installation surface.

The step 263 is provided with first intake ports 264, a mesh 265, second intake ports 266, third intake ports 267, and an adjustable leg 268. That is, the exterior housing 2 has the first intake ports 264 and the mesh 265.

The first intake ports 264 are disposed at positions shifted from the protrusion 261 toward the negative end of the Z direction. That is, the first intake ports 264 are provided at positions on the bottom surface 26 that are shifted toward the rear surface 22. The first intake ports 264 are a plurality of openings arranged along the X-axis. When a first fan 51, which will be described later and is disposed in the exterior housing 2, is driven, the air outside the exterior housing 2 is introduced into the exterior housing 2 via the first intake ports 264. The step 263 has a configuration in which the portion where the first intake ports 264 are provided is continuous with the rear surface 22.

The mesh 265 is provided inside the exterior housing 2 in correspondence with the first intake ports 264, and captures dirt and dust contained in the outside air flowing through the first intake ports 264. The openings of the mesh 265 are rougher than those of the fabric 2C1 of the fabric unit 2C. The flow path resistance exerted on the outside air passing through the first intake ports 264 is therefore smaller than the flow path resistance exerted on the outside air passing through the communication ports 2CA1.

The second intake ports 266 are disposed at a portion of the bottom surface 26 that is shifted toward the positive end of the X direction and the positive end of the Z direction, and the third intake ports 267 are disposed at a portion of the bottom surface 26 that is shifted toward the negative end of the X direction and the positive end of the Z direction.

The intake ports 264, 266, and 267 introduce the air outside the exterior housing 2 as the cooling gas into the exterior housing 2. The cooling gas introduced into the exterior housing 2 is caused to flow to cooling targets by fans 51, 54, and 55 of a cooling apparatus 5, which will be described later. The cooling gas having cooled the cooling targets is discharged out of the exterior housing 2 via the discharge ports 241 and 242.

The adjustable leg 268 is provided at a position sandwiched between the second intake ports 266 and the third intake ports 267 on the X-axis. The adjustable leg 268 is a leg capable of adjusting the amount of protrusion from the bottom surface 26, and is one of the contact portions that come into contact with the installation surface.

### Configuration of Inclining Surface

The inclining surface 27 is provided as part of the lower case 2B so as to extend along the front surface 21, the rear surface 22, the right side surface 23, the left side surface 24, and the bottom surface 26. The inclining surface 27 includes a front inclining surface 27A, a rear inclining surface 27B, a right inclining surface 27C, and a left inclining surface 27D.

The front inclining surface 27A is formed of a portion of the front surface 21 that is shifted toward the negative end of the Y direction and a portion of the bottom surface 26 that is shifted toward the positive end of the Y direction. The front inclining surface 27A is a surface that extends along the front surface 21 and the bottom surface 26 and approaches the installation surface as extending toward the rear surface 22, which is opposite from the front surface 21. That is, a portion of the front inclining surface 27A that is shifted toward the negative end of the Y direction inclines with respect to the front surface 21, and a portion of the front inclining surface 27A that is shifted toward the positive end of the Y direction inclines with respect to the bottom surface 26.

The rear inclining surface 27B is formed of a portion of the rear surface 22 that is shifted toward the negative end of the Y direction and a portion of the bottom surface 26 that is shifted toward the positive end of the Y direction.

The right inclining surface 27C is formed of a portion of the right side surface 23 that is shifted toward the negative end of the Y direction and a portion of the bottom surface 26 that is shifted toward the positive end of the Y direction.

The left inclining surface 27D is formed of a portion of the left side surface 24 that is shifted toward the negative end of the Y direction and a portion of the bottom surface 26 that is shifted toward the positive end of the Y direction.

The rear inclining surface 27B, the right inclining surface 27C, and the left inclining surface 27D each incline as the front inclining surface 27A does.

### Internal Configuration of Exterior Housing

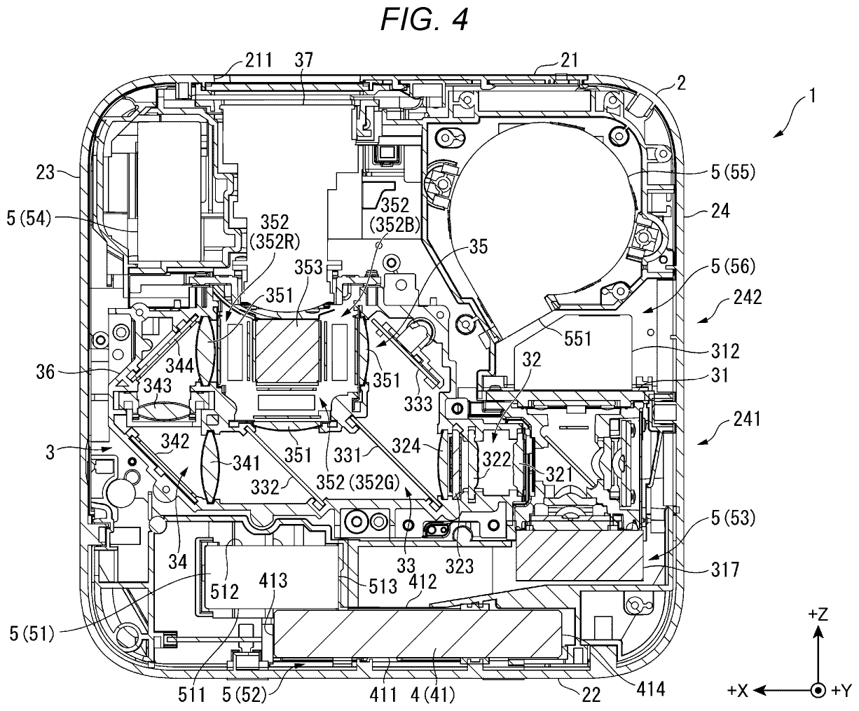

FIG. 4 shows a cross section of the projector 1 taken along an XZ plane.

The projector 1 includes, in addition to the exterior housing 2, an image projection apparatus 3, a wireless communication apparatus 4, and the cooling apparatus 5, which are disposed in a portion of the exterior housing 2 that is shifted toward the positive end of the Y direction, as shown in FIG. 4.

In addition, although not shown, the projector 1 includes a control substrate disposed at a position shifted toward the positive end of the Y direction from the image projection apparatus 3, the wireless communication apparatus 4, and the cooling apparatus 5. The control substrate controls the operation of the projector 1.

### Configuration of Image Projection Apparatus

The image projection apparatus 3 generates image light according to image information and projects the generated image light. The image projection apparatus 3 is provided substantially at the center of the exterior housing 2 and along the X-axis and the Z-axis. The image projection apparatus 3 includes a light source apparatus 31, a homogenizing system 32, a color separation system 33, a relay system 34, an image formation unit 35, an optical part housing 36, and a projection optical apparatus 37.

The light source apparatus 31 is provided at a position shifted toward the negative end of the X direction and located substantially at the center of the Z-axis in the exterior housing 2, and outputs illumination light toward the positive end of the X direction. The configuration of the light source apparatus 31 will be described later in detail.

The homogenizing system 32 homogenizes the illumination light output from the light source apparatus 31. The homogenized illumination light travels via the color separation system 33 and the relay system 34 and illuminates a light modulation region of each light modulator 352, which will be described later. The homogenizing system 32 includes two lens arrays 321 and 322, a polarization converter 323, and a superimposing lens 324.

The color separation system 33 separates the illumination light incident from the homogenizing system 32 into red light, green light, and blue light. The color separation system 33 includes two dichroic mirrors 331 and 332 and a reflection mirror 333, which reflects the blue light separated by the dichroic mirror 331.

The relay system 34 is provided in the optical path of the red light, which is longer than the optical paths of the other color light, and suppresses loss of the red light. The relay system 34 includes a light-incident-side lens 341, a relay lens 343, reflection mirrors 342 and 344. Note that the blue light may be set as the color light having a longer optical path than those of the other color light, and the relay system 34 may be provided in the optical path of the blue light.

The image formation unit 35 modulates the red light, the green light, and the blue light incident thereon and combines the modulated three types of color light with one another to form the image light. The image formation unit 35 includes three field lenses 351, which are provided in accordance with the incident three types of color light, three light modulators 352, which modulate the light incident thereon, and one light combiner 353. That is, the image formation unit 35 includes the optical modulators 352 and forms the image light.

The three light modulators 352 include a light modulator 352R, which modulates the red light, a light modulator 352G, which modulates the green light, and a light modulator 352B, which modulates the blue light. The light modulators 352 can be each formed, for example, of a liquid crystal panel and a pair of polarizing plates that sandwich the liquid crystal panel. The light modulators 352 are each a heat source that generates heat when light is incident thereon.

The light combiner 353 combines the three types of color light modulated by the light modulators 352B, 352G, and 352R with one another to form the image light and outputs the formed image light to the projection optical apparatus 37. In the present embodiment, the light combiner 353 is formed of a cross dichroic prism, but not necessarily, and can instead be formed, for example, of a plurality of dichroic mirrors.

The optical part housing 36 accommodates the homogenizing system 32, the color separation system 33, and the relay system 34.

The projection optical apparatus 37 is a projection lens that enlarges the image light incident from the image formation unit 35 and projects the enlarged image light onto the projection receiving surface. The projection optical apparatus 37 can, for example, be an assembled lens including a plurality of lenses and a tubular lens barrel that accommodates the plurality of lenses.

### Configuration of Light Source Apparatus

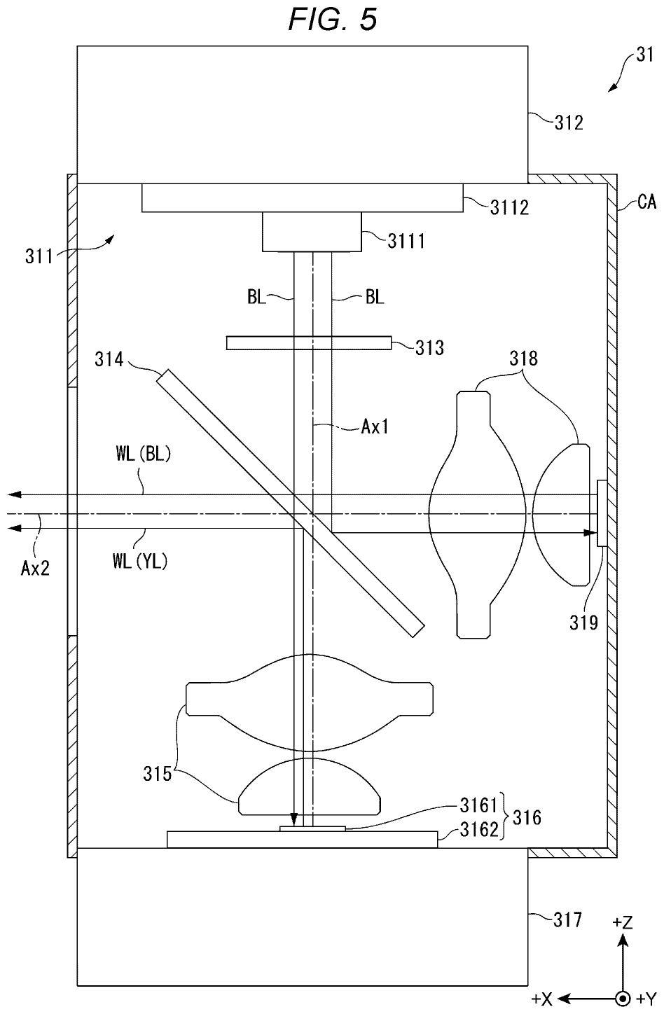

FIG. 5 is a diagrammatic view showing the configuration of the light source apparatus 31.

The light source apparatus 31 outputs illumination light WL, toward the homogenizing system 32 in the X direction toward the positive end thereof. The light source apparatus 31 includes a light source 311, a first heat dissipation member 312, a diffusively transmissive part 313, a light separator 314, a first light collector 315, a wavelength converter 316, a second heat dissipation member 317, a second light collector 318, a diffusive reflector 319, and a light source housing CA, as shown in FIG. 5.

The following axes are set in the light source apparatus 31: an optical axis Ax1 extending along the Z-axis; and an optical axis Ax2 extending along the X-axis, and the optical axes Ax1 and Ax2 are perpendicular to each other. The optical parts of the light source apparatus 31 are disposed on the optical axis Ax1 or the optical axis Ax2.

Specifically, the light source 311, the diffusively transmissive part 313, the light separator 314, the first light collector 315, and the wavelength converter 316 are disposed on the optical axis Ax1.

The diffusive reflector 319, the second light collector 318, and the light separator 314 are disposed on the optical axis Ax2. That is, the light separator 314 is disposed at the intersection of the optical axis Ax1 and the optical axis Ax2.

The optical axis Ax2 is linked to the optical axis of the image projection apparatus 3 at the lens array 321 of the homogenizing system 32.

### Configuration of Light Source Housing

The light source housing CA accommodates the light source 311, the diffusively transmissive part 313, the light separator 314, the first light collector 315, the wavelength converter 316, the second light collector 318, and the diffusive reflector 319. In the present embodiment, the light source housing CA is a sealed housing that dirt and dust is unlikely to enter, but not necessarily. The light source housing CA only needs to accommodate the optical parts described above.

### Configuration of Light Source

The light source 311 outputs light toward the negative end of the Z direction. The light source 311 includes a light emitter 3111 and a substrate 3112.

The light emitter 3111 emits blue light BL. The blue light BL is excitation light that excites a phosphor of the wavelength converter 316. The light emitter 3111 is a semiconductor laser that outputs laser light having a peak wavelength of 455 nm.

The substrate 3112 is fixed to the light source housing CA while supporting the light emitter 3111. The substrate 3112 receives heat from the light emitter 3111 and transfers the received heat to the first heat dissipation member 312. That is, the substrate 3112 functions as a support substrate that supports the light emitter 3111, and also functions as a heat receiving substrate that receives the heat from the light emitter 3111.

### Configuration of First Heat Dissipation Member

The first heat dissipation member 312 is a heat sink that is exposed to the space outside the light source housing CA and dissipates the heat transferred from the light source 311 out of the light source housing CA. In detail, the first heat dissipation member 312 is disposed in a third duct 56, which will be described later, of the cooling apparatus 5, and dissipates the heat of the light emitter 3111 transferred from the substrate 3112. The first heat dissipation member 312 transfers the heat of the light emitter 3111 to the cooling gas flowing from the third fan 55, which will be described later, to cool the light emitter 3111.

### Configuration of Diffusively Transmissive Part

The diffusively transmissive part 313 diffuses the blue light BL incident from the light source 311 and outputs light having a homogenized illuminance distribution. The blue light BL output from the diffusively transmissive part 313 is incident on the light separator 314. The diffusively transmissive part 313 can, for example, have a configuration including a hologram, a configuration in which a plurality of lenslets are arranged in a plane perpendicular to the optical axis, or a configuration in which a light passage surface is a rough surface.

In place of the diffusively transmissive part 313, the light source apparatus 31 may employ a homogenizer optical element including a pair of multi-lens arrays. On the other hand, when the diffusively transmissive part 313 is employed, the distance from the light source 311 to the light separator 314 can be reduced as compared with the case where the homogenizer optical element is employed.

### Configuration of Light Separator

The light separator 314 has the function of a half-silvered mirror that transmits part of the blue light BL incident thereon from the light source 311 via the diffusively transmissive part 313 and reflects the remainder of the blue light BL. That is, the light separator 314 transmits first partial light that is part of the blue light BL incident from the diffusively transmissive part 313 toward the negative end of the Z direction to cause the transmitted light to enter the first light collector 315, and reflects second partial light that is the remainder of the blue light BL toward the negative end of the X direction to cause the reflected light to enter the second light collector 318.

The light separator 314 further has the function of a dichroic mirror that reflects fluorescence YL incident from the wavelength converter 316 in the Z direction toward the positive end thereof and transmits the blue light BL incident from the diffusive reflector 319 in the X direction toward the positive end thereof.

### Configuration of First Light Collector

The first light collector 315 causes the first partial light having passed through the light separator 314 to be collected at the wavelength converter 316. Furthermore, the first light collector 315 parallelizes the fluorescence YL incident from the wavelength converter 316.

### Configuration of Wavelength Converter

The wavelength converter 316 is a reflective wavelength converter that converts the wavelength of the light incident thereon, diffuses the converted light in the opposite direction of the direction of the incident light, and outputs the diffused light. The wavelength converter 316 includes a phosphor layer 3161 and a substrate 3162, and is directly or indirectly fixed to the light source housing CA.

The phosphor layer 3161 contains a phosphor excited by the blue light BL incident thereon, which is excitation light, and outputs the fluorescence YL having wavelengths longer than the wavelength of the incident blue light BL. The light output from the phosphor layer 3161 is the fluorescence YL, which is non-polarized light and has peak wavelengths ranging, for example, from 500 to 700 nm, and the fluorescence YL contains green light and red light.

The substrate 3162 supports the phosphor layer 3161 and receives heat from the phosphor layer 3161. Although not shown, a reflective layer that reflects the light incident from the phosphor layer 3161 is provided between the phosphor layer 3161 and the substrate 3162. Instead, the surface of the substrate 3162 at which the phosphor layer 3161 is provided may function as a reflection surface.

The fluorescence YL output from the wavelength converter 316 passes through the first light collector 315 along the optical axis Ax1 and is incident on the light separator 314. The fluorescence YL incident on the light separator 314 is reflected off the light separator 314 toward the positive end of the X direction, and exits out of the light source apparatus 31 along the optical axis Ax2.

### Configuration of Second Heat Dissipation Member

The second heat dissipation member 317 is a heat sink that is exposed to the space outside the light source housing CA and dissipates the heat transferred from the wavelength converter 316 out of the light source housing CA. In detail, the second heat dissipation member 317 is disposed in a second duct 53, which will be described later, and dissipates the heat of the phosphor layer 3161 transferred from the substrate 3162. The second heat dissipation member 317 transfers the heat of the phosphor layer 3161 to the cooling gas flowing from the first fan 51, which will be described later, to cool the wavelength converter 316.

### Configuration of Second Light Collector

The second light collector 318 causes the second partial light incident from the light separator 314 to be collected at the diffusive reflector 319. The second light collector 318 parallelizes the blue light incident from the diffusive reflector 319.

### Configuration of Diffusive Reflector

The diffusive reflector 319 is fixed to the inner surface of the light source housing CA. The diffusive reflector 319 diffusively reflects the blue light BL incident from the second light collector 318 at the diffusion angle substantially equal to the diffusion angle of the fluorescence YL output from the wavelength converter 316 or the diffusion angle slightly smaller than the diffusion angle of the fluorescence YL. That is, the diffusive reflector 319 diffusively reflects the light incident thereon without converting the wavelength of the incident light.

The blue light BL reflected off the diffusive reflector 319 toward the positive end of the X direction passes through the second light collector 318, then passes through the light separator 314 toward the positive end of the X direction, and exits out of the light source apparatus 31 along with the fluorescence YL.

As described above, the illumination light WL, which exits out of the light source apparatus 31, is white light that is the mixture of the blue light BL and the fluorescence YL containing green light and red light.

### Configuration of Wireless Communication Apparatus

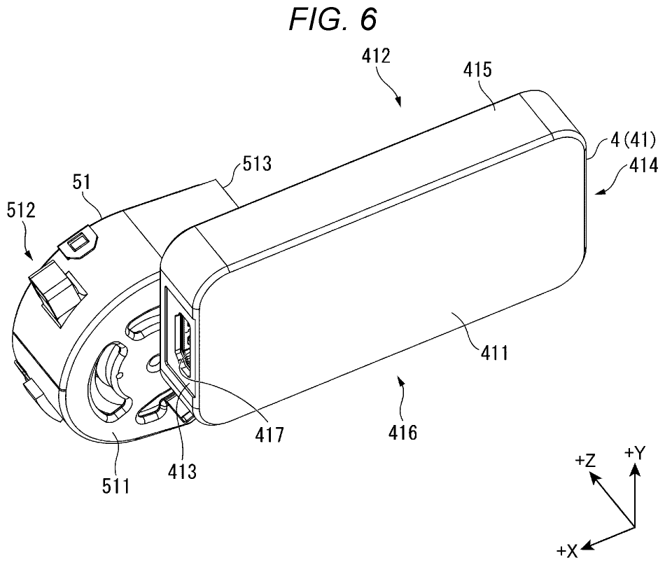

FIG. 6 is a perspective view showing the wireless communication apparatus 4 and the first fan 51 of the cooling apparatus 5.

The wireless communication apparatus 4 shown in FIG. 4 is electrically coupled to the control substrate described above, and wirelessly communicates with an external device that is not shown, for example, a video output apparatus. In detail, the wireless communication apparatus 4 receives a video signal from the video output apparatus and outputs the received video signal to the control substrate. The wireless communication apparatus 4 is disposed on the side opposite from the image formation unit 35 with respect to the first fan 51, which constitutes the cooling apparatus 5, which will be described later, and a second flow path of the second duct 53, which constitutes the cooling apparatus 5.

The wireless communication apparatus 4 includes a housing 41 and a communication apparatus body that is not shown but is provided in the housing 41, as shown in FIG. 6.

The housing 41 has a first surface 411, a second surface 412, a third surface 413, a fourth surface 414, a fifth surface 415, and a sixth surface 416, and is formed in a rectangular box-like shape elongated along the X-axis.

The first surface 411 and the second surface 412 are surfaces opposite from each other along the Z-axis.

The first surface 411 is a surface that faces the negative end of the Z direction and opposes the inner side of the rear surface 22 along the Z-axis.

The second surface 412 is a surface that faces the positive end of the Z direction, and opposes an intake portion 511 of the first fan 51, which will be described later.

The third surface 413 and the fourth surface 414 are surfaces opposite from each other along the X-axis.

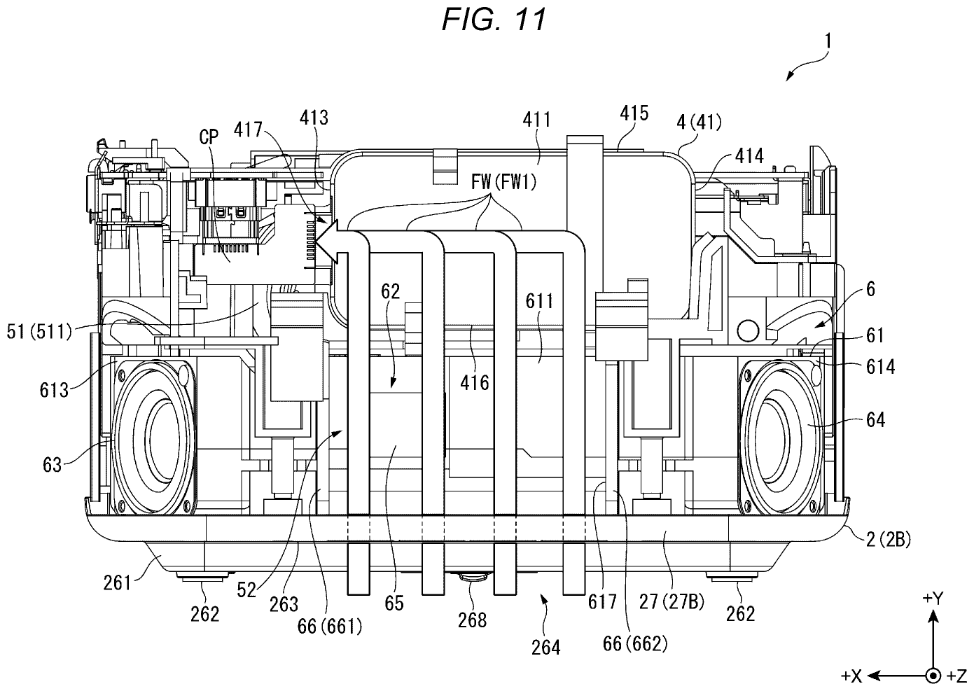

The third surface 413 is a surface facing the positive end of the X direction. The third surface 413 has a terminal 417 to which a coupling substrate CP, which is not shown in FIG. 6, can be coupled. The coupling substrate CP couples the control substrate and the wireless communication apparatus 4 to each other. The coupling substrate CP is shown in FIG. 11, which will be described later.

The fourth surface 414 is a surface facing the negative end of the X direction.

The fifth surface 415 and the sixth surface 416 are surfaces opposite from each other along the Y-axis.

The fifth surface 415 is a surface facing the positive end of the Y direction and opposes the inner side of the top surface 25.

The sixth surface 416 is a surface that faces the negative end of the Y direction and opposes the speaker unit 6, which will be described later, along the Y-axis.

The wireless communication apparatus 4 having the thus configured housing 41 is disposed inside the exterior housing 2 along the rear surface 22, as shown in FIG. 4. The wireless communication apparatus 4 is cooled by the cooling gas caused to flow by the first fan 51.

### Configuration of Cooling Apparatus

The cooling apparatus 5 shown in FIG. 4 cools the cooling targets that constitute the projector 1. The cooling apparatus 5 includes the first fan 51, a first duct 52, the second duct 53, the second fan 54, the third fan 55, and the third duct 56. The first fan 51, the first duct 52, the second duct 53, the second fan 54, the third fan 55, and the third duct 56 are each provided inside the exterior housing 2.

The first fan 51, the first duct 52, and the second duct 53 will be described later in detail.

### Configuration of Second Fan

The second fan 54 is provided inside the exterior housing 2 at the corner facing the positive end of the X direction and the positive end of the Z direction. The second fan 54 sucks the air outside the exterior housing 2 as the cooling gas via the second intake ports 266, and sends the sucked cooling gas to the optical modulators 352 and the control substrate, the latter of which is disposed at a position shifted from the image projection apparatus 3 toward the positive end of the Y direction.

The cooling gas sent by the second fan 54 causes the portion where the image projection apparatus 3 and the control substrate are disposed inside the exterior housing 2 to have a positive pressure. On the other hand, although not shown in detail, the space shifted from the control substrate toward the positive end of the Y direction communicates with the discharge ports 241.

Therefore, the cooling gas having cooled the image formation unit 35, which includes the light modulators 352, and the control substrate is pushed out by the positive pressure toward the discharge ports 241, and drawn by the flow of the cooling gas flowing through the second duct 53 and discharged via the discharge ports 241, so that the cooling gas is discharged out of the exterior housing 2 via the discharge ports 241.

### Configurations of Third Fan and Third Duct

The third fan 55 is provided inside the exterior housing 2 at the corner facing the negative end of the X direction and the positive end of the Z direction. The third fan 55 sucks the air outside the exterior housing 2 as the cooling gas via the third intake ports 267, and sends the sucked cooling gas to the first heat dissipation member 312. An air sending port 551 of the third fan 55 opens into the third duct 56.

The cooling gas sent from the third fan 55 flows through the third duct 56, which couples the air sending port 551 of the third fan 55 to the discharge ports 242, which open through the left side surface 24. Since the first heat dissipation member 312 is disposed in the third duct 56, the cooling gas sent from the third fan 55 into the third duct 56 cools the first heat dissipation member 312 as described above, and is then discharged out of the exterior housing 2 via the discharge ports 242.

### Configuration of Speaker Unit

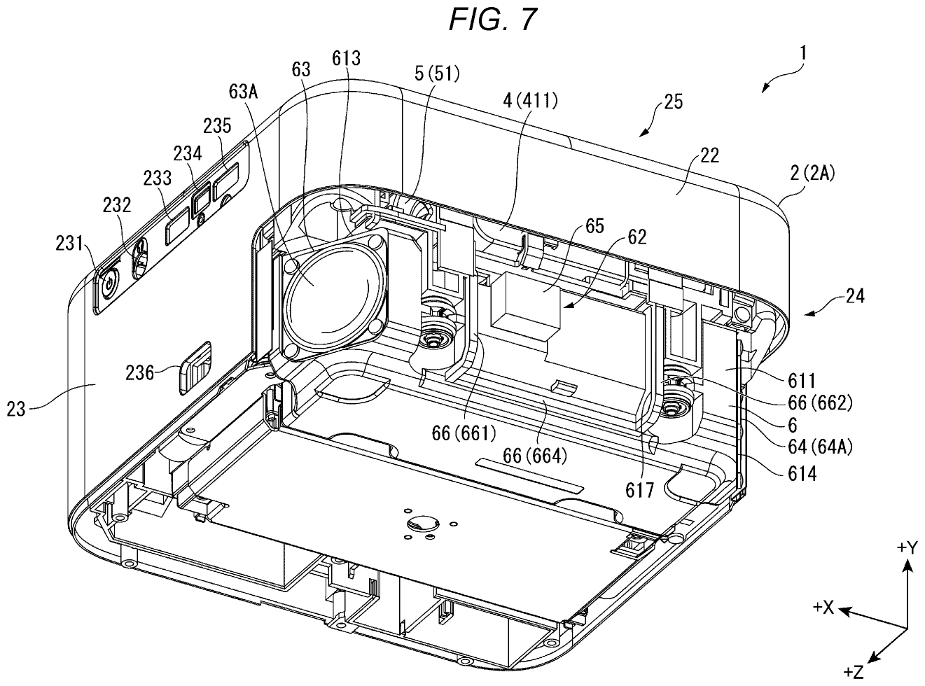

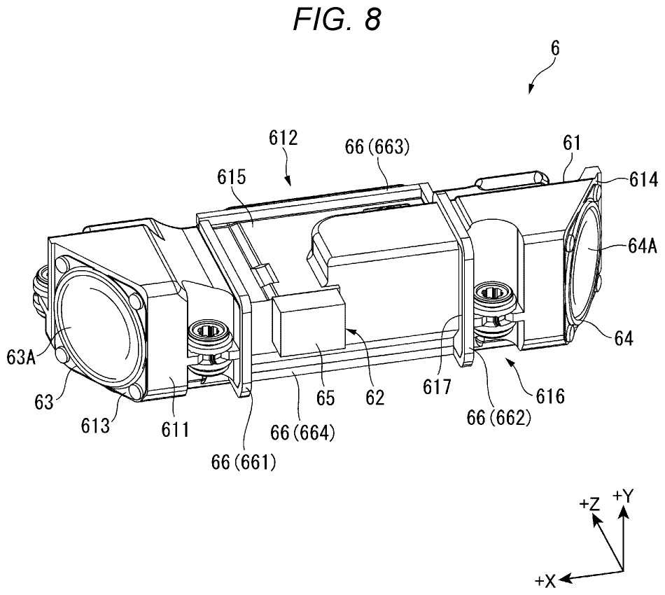

FIG. 7 is a perspective view of the projector 1 viewed from the side facing the rear surface thereof with the lower case 2B and the fabric unit 2C removed. FIG. 8 is a perspective view showing the speaker unit 6.

In addition to the configuration described above, the projector 1 further includes the speaker unit 6, which is disposed in the exterior housing 2, as shown in FIG. 7.

The speaker unit 6 is disposed in a portion of the exterior housing 2 that is shifted toward the negative end of the Y direction and the negative end of the Z direction, and outputs voice according to a voice signal input from the control substrate. In addition, the speaker unit 6, which is disposed in the exterior housing 2, constitutes, along with the inner surface of the rear surface 22, the first duct 52.

The speaker unit 6 includes a speaker housing 61, a first sound emitter 62, second sound emitters 63 and 64, a porous member 65, and a sealer 66, as shown in FIGS. 7 and 8.

The speaker housing 61 is an enclosure that supports the first sound emitter 62, the second sound emitters 63 and 64, the porous member 65, and the sealer 66. The speaker enclosure 61 has a first surface 611, a second surface 612, a third surface 613, a fourth surface 614, a fifth surface 615, and a sixth surface 616, and is formed in a lateral truncated quadrangular pyramidal shape, as shown in FIG. 8. That is, the speaker housing 61 is so shaped that the dimension thereof along the X-axis decreases as the speaker housing 61 extends toward the negative end of the Z direction.

The first surface 611 is a surface facing the negative end of the Z direction and opposes the inner surface of the rear surface part 2CA of the fabric unit 2C. In detail, the first surface 611 opposes the communication ports 2CA1 of the rear surface part 2CA.

The first surface 611 is provided with a recess 617, which is recessed toward the positive end of the Z direction. That is, the speaker housing 61 has the recess 617. As will be described later in detail, the recess 617 widens the flow path through which the cooling gas introduced into the exterior housing 2 via the first intake ports 264 flows.

The second surface 612 is a surface opposite from the first surface 611.

The third surface 613 is a surface facing the positive end of the X direction and the negative end of the Z direction. That is, the third surface 613 is an inclining surface inclining with respect to each of the XY plane and the YZ plane.

The fourth surface 614 is a surface facing the negative end of the X direction and the negative end of the Z direction. That is, the fourth surface 614 is an inclining surface inclining with respect to each of the XY plane and the YZ plane.

The fifth surface 615 is a surface that faces the positive end of the Y direction and opposes the wireless communication apparatus 4 and the first fan 51.

The sixth surface 616 is a surface that faces the negative end of the Y direction and opposes the inner surface of the bottom surface 26. That is, the sixth surface 616 opposes the first intake ports 264.

The thus configured speaker housing 61 is disposed so as to oppose the communication ports 2CA1 and the first intake ports 264.

The first sound emitter 62 is provided at the first surface 611. In detail, the first sound emitter 62 is disposed at the bottom of the recess 617. The first sound emitter 62 is the exit-side port of a bass reflex duct that is not shown but is provided in the speaker housing 61. The first sound emitter 62 therefore outputs a low-pitched sound. The entrance-side port of the bass reflex duct is disposed in the speaker housing 61.

The speaker housing 61 is provided with the porous member 65, which covers at least part of the first sound emitter 62, as shown in FIGS. 7 and 8. In the present embodiment, the porous member 65 is provided so as to cover the entire first sound emitter 62 when viewed from the side facing the negative end of the Z direction.

The porous member 65 reduces the flow speed of the air flowing through the bass reflex duct at the exit-side port. The thus configured porous member 65 slows down the flow of air coming out of the bass reflex duct to reduce port noise and wind noise generated at the exit-side port.

The porous member 65 is in contact with the inner surface of the fabric unit 2C. The porous member 65 thus suppresses noise generated due to vibration of the fabric unit 2C caused by the low-pitched sound emitted from the first sound emitter 62. The porous member 65 can be made, for example, of sponge.

The second sound emitters 63 and 64 each emit voice according to the voice signal input from the control substrate. The second sound emitters 63 and 64 are each a full-range speaker, and can emit a higher-pitched sound than the sound emitted from the first sound emitter 62. That is, the second sound emitters 63 and 64 can each emit a sound different in terms of pitch from the sound emitted from the first sound emitter 62.

The second sound emitter 63 is provided at the third surface 613, and a sound emission surface 63A, via which the second sound emitter 63 emits the sound, faces the positive end of the X direction and the negative end of the Z direction. The sound emitted from the second sound emitter 63 exits out of the exterior housing 2 via the right sound emission ports 2CR1 and the fabric 201 of the fabric unit 2C.

The second sound emitter 64 is provided at the fourth surface 614, and a sound emission surface 64A, via which the second sound emitter 64 emits the sound, faces the negative end of the X direction and the negative end of the Z direction. The sound emitted from the second sound emitter 64 exits out of the exterior housing 2 via the left sound emission ports 2CL1 and the fabric 201 of the fabric unit 2C.

Arranging the second sound emitters 63 and 64 as described above allows effective spread of the sound outside the exterior housing 2.

The sealer 66 is provided between the inner surface of the fabric unit 2C, which constitutes the exterior housing 2, and the speaker housing 61, and seals the space between the inner surface of the fabric unit 2C and the outer surface of the speaker housing 61. In the present embodiment, the sealer 66 is fixed to the speaker housing 61 with an adhesive or a double-sided adhesive tape.

In detail, the sealer 66 is provided across the first surface 611, the fifth surface 615, and the sixth surface 616. The sealer 66 is provided between the speaker housing 61 and the inner surface of the exterior housing 2, and surrounds the first sound emitter 62 to separate the space in which the first sound emitter 62 is disposed from the space in which the second sound emitters 63 and 64 are disposed. That is, the sealer 66 separates the second sound emitters 63 and 64 from the airflow that the first fan 51 causes to flow through the space in which the first sound emitter 62 is disposed.

The sealer 66 includes a first sealer 661, a second sealer 662, a third sealer 663, and a fourth sealer 664, as shown in FIG. 8. The sealer 66 has the shape of a frame formed by the sealers 661 to 664 coupled to each other.

The first sealer 661 and the second sealer 662 are provided across the first surface 611, the fifth surface 615, and the sixth surface 616 in the speaker housing 61. The first sealer 661 is disposed between the first sound emitter 62 and the second sound emitter 63 along the X-axis, and the second sealer 662 is disposed between the first sound emitter 62 and the second sound emitter 64 along the X-axis. In the present embodiment, the first intake ports 264 and the communication ports 2CA1 open to the space between the first sealer 661 and the second sealer 662. The sealers 661 and 662 therefore cause the outside air introduced into the exterior housing 2 via the first intake ports 264 or the communication ports 2CA1 to flow between the first sealer 661 and the second sealer 662 toward the positive end of the Y direction without flowing to the second sound emitters 63 and 64.

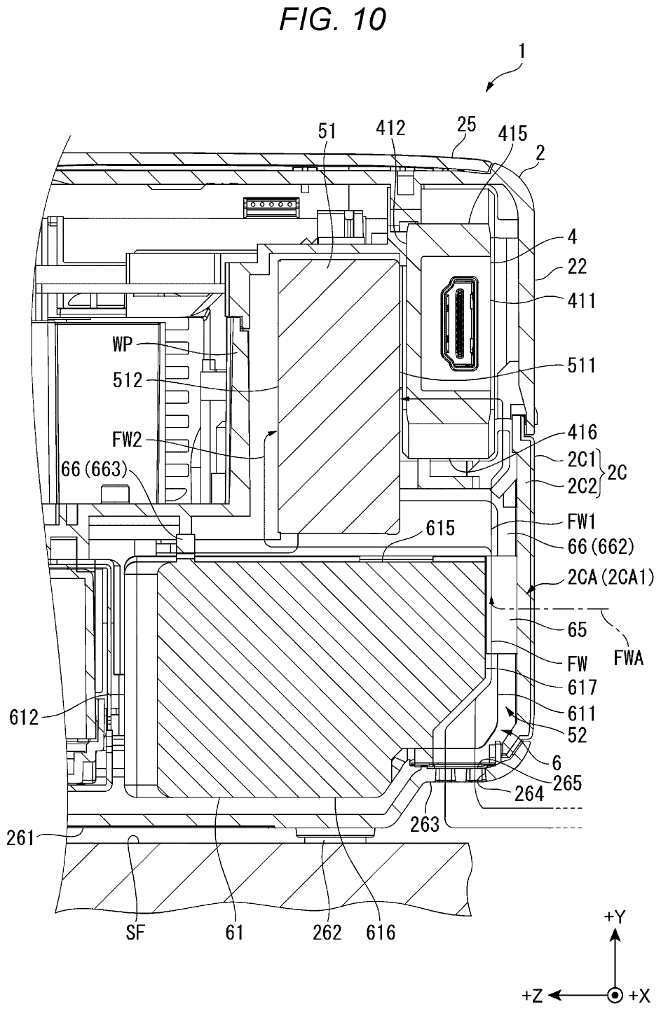

The third sealer 663 is provided along the X-axis at a portion of the fifth surface 615 that faces the positive end of the Z direction. The first sealer 661 and the second sealer 662 are each coupled to the third sealer 663. The third sealer 663 seals the space between the speaker housing 61 and a wall WP, which separates the image projection apparatus 3 from the first fan 51 and the wireless communication apparatus 4 in the exterior housing 2. The wall WP is shown in FIG. 10, which will be described later.

The fourth sealer 664 is provided along the X-axis at a portion of the sixth surface 616 that faces the positive end of the Z direction. The first sealer 661 and the second sealer 662 are each coupled to the fourth sealer 664. The fourth sealer 664 seals the space between the inner side of the bottom surface 26 and the speaker housing 61.

The thus configured speaker unit 6 disposed inside the exterior housing 2 constitutes part of the first duct 52.

### Configuration of First Fan

The first fan 51 shown in FIG. 4 is a double-sided-intake sirocco fan including intake portions 511 and 512 and a sending portion 513. The first fan 51 is disposed adjacent to the wireless communication apparatus 4 in the Z direction toward the positive end thereof, which is the direction from the first surface 411 toward the second surface 412, with respect to the wireless communication apparatus 4 in such a way that the intake portion 511 faces the negative end of the Z direction, the intake portion 512 faces the positive end of the Z direction, and the sending portion 513 faces the negative end of the X direction. In detail, part of the first fan 51 is disposed so as to oppose and overlap with the second surface 412 of the wireless communication apparatus 4 without the intake portion 511 being blocked, as shown in FIG. 6. The intake portion 511 is disposed at a position where the intake portion 511 opposes the coupling substrate CP, which will be described later. The coupling substrate CP is coupled to the terminal 417 of the wireless communication apparatus 4.

The first fan 51 causes the cooling gas introduced into the exterior housing 2 to flow to first and second cooling targets to cool the cooling targets, as shown in FIG. 4. Specifically, the first fan 51 sucks the cooling gas flowing through the first duct 52 and sends the sucked cooling gas to the second duct 53. The first fan 51 thus causes the cooling gas to flow to the wireless communication apparatus 4 as the first cooling target and the second heat dissipation member 317 as the second cooling target to cool the wireless communication apparatus 4 and the second heat dissipation member 317. The heat is transferred from the wavelength converter 316 to the second heat dissipation member 317, as described above.

### Configuration of First Duct

The first duct 52 is a duct through which the first fan 51 takes in the air, and causes the cooling gas introduced into the exterior housing 2 via the first intake ports 264 and the communication ports 2CA1 to flow to the first fan 51. That is, the first duct 52 causes the first fan 51 to communicate with the communication ports 2CA1 and the first intake ports 264, and the first fan 51 sucks the air outside the exterior housing 2 through the first duct 52.

The first duct 52 is formed by the inner side of the rear surface 22 of the exterior housing 2, the speaker housing 61 of the speaker unit 6, and the first surface 411 of the wireless communication apparatus 4.

Flow of Cooling Gas Introduced into Exterior Housing

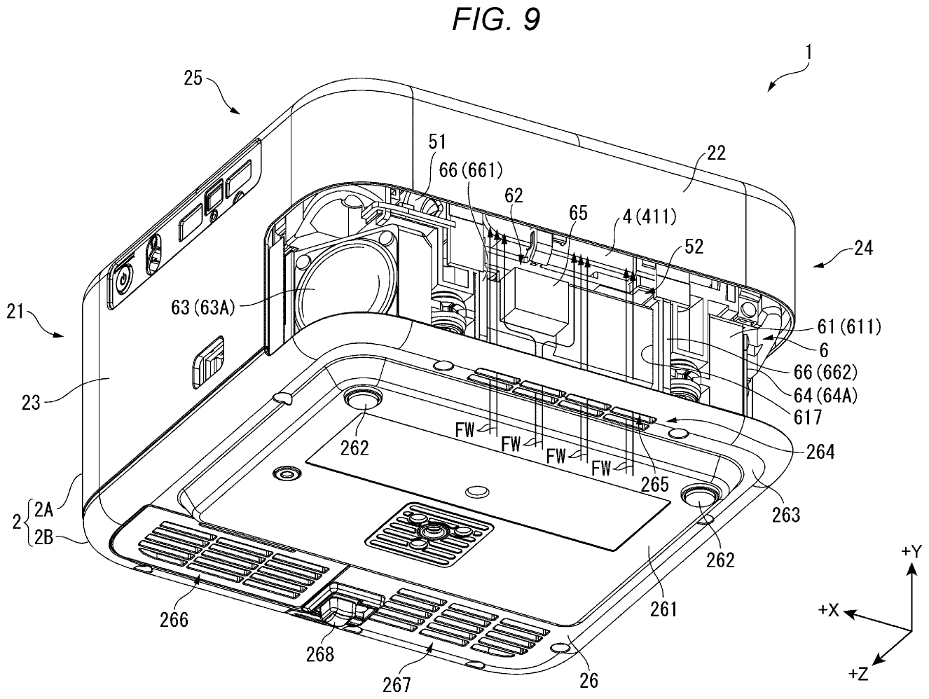

FIGS. 9 and 10 describe the flow of the cooling gas introduced into the exterior housing 2. In other words, FIG. 9 is a perspective view of the projector 1 viewed from the side facing the rear surface thereof, and FIG. 10 is a cross-sectional view of the projector 1 taken along a YZ plane. Note in FIG. 9 that the fabric unit 2C is not shown to show the airflow in the exterior housing 2.

When the first fan 51 is driven, the air outside the exterior housing 2 is introduced as a cooling gas FW into the exterior housing 2 via the introduction ports separate from an installation surface SF, the first intake ports 264 and/or the communication ports 2CA1, as shown in FIGS. 9 and 10. Since the flow path resistance exerted on the cooling gas passing through the communication ports 2CA1 is greater than the flow path resistance exerted on the cooling gas passing through the first intake ports 264 provided at the bottom surface 26, the cooling gas FW passing through the first intake ports 264 is the primary cooling gas introduced into the exterior housing 2. When the first intake ports 264 are blocked, a cooling gas FWA passing through the communication ports 2CA1 is the primary cooling gas introduced into the exterior housing 2, as indicated by the chain-line arrow in FIG. 10.

The flow direction of the cooling gas FW will be described below, and the flow direction of the cooling gas FWA introduced into the exterior housing 2 via the communication ports 2CA1 is also the same as the flow direction of the cooling gas FW introduced into the exterior housing 2 via the first intake ports 264.

The cooling gas FW introduced into the exterior housing 2 flows toward the positive end of the Y direction through the first duct 52, which is formed by the first sealer 661, the second sealer 662, the first surface 611 of the speaker housing 61, and the inner surface of the fabric unit 2C. The recess 617, which is recessed toward the positive end of the Z direction, is provided between the first sealer 661 and the second sealer 662, and the first sound emitter 62 is provided at the bottom of the recess 617, as described above.

FIG. 11 describes the flow of a cooling gas FW1 introduced into the exterior housing 2 via the first intake ports 264.

The cooling gas FW flowing through the first duct 52 further flows toward the positive end of the Y direction while detouring the porous member 65 provided in correspondence with the first sound emitter 62. The cooling gas FW1, which is part of the cooling gas FW having flowed toward the positive end of the Y direction, then further flows toward the positive end of the Y direction beyond the speaker housing 61 and reaches the wireless communication apparatus 4, as shown in FIG. 10.

The cooling gas FW1 is then sucked by the intake portion 511 of the first fan 51 and flows toward the intake portion 511 in the X direction toward the positive end thereof along the first surface 411 of the wireless communication apparatus 4, as shown in FIG. 11. That is, part of the first duct 52 is formed by the first surface 411. The thus flowing cooling gas FW1 cools a portion of the wireless communication apparatus 4 that faces the first surface 411.

Furthermore, the intake portion 511 opposes the coupling substrate CP coupled to the terminal 417 of the wireless communication apparatus 4. Therefore, when the intake portion 511 sucks the cooling gas FW1, the cooling gas FW1 flows to the coupling substrate CP to cool the coupling substrate CP.

The cooling gas FW1, which is part of the cooling gas FW introduced by the intake portion 511 of the first fan 51 into the exterior housing 2 via at least one of the introduction ports, the first intake ports 264 or the communication ports 2CA1, is sucked, so that the sucked cooling gas FW1 flows along the first surface 411 of the wireless communication apparatus 4 to cool a portion of the wireless communication apparatus 4 that faces the first surface 411.

A cooling gas FW2, which is another part of the cooling gas FW having flowed toward the positive end of the Y direction with respect to the speaker housing 61, flows between the first fan 51 and the fifth surface 615 of the speaker housing 61 toward the positive end of the Z direction, and is sucked by the intake portion 512 of the first fan 51.

The first surface 411 of the wireless communication apparatus 4 does not oppose the first intake ports 264 or the communication ports 2CA1. The first intake ports 264 and the communication ports 2CA1 are shifted from the first surface 411 toward the negative end of the Y direction. The cooling gas FW1 therefore flows from the side facing the negative end of the Y direction across the entire first surface 411. The introduction ports via which the cooling gas flowing through the wireless communication apparatus 4 is introduced into the exterior housing 2 may instead be disposed at positions where the introduction ports face the first surface 411 of the wireless communication apparatus 4.

### Configuration of Second Duct

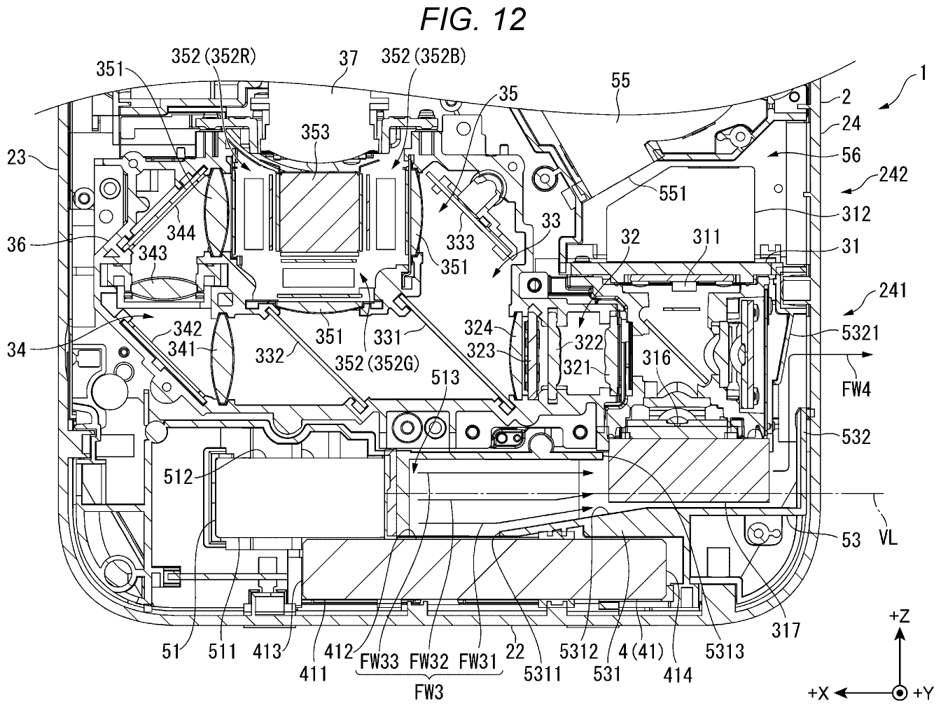

FIG. 12 shows the second duct 53 and the flow of the cooling gas through the second duct 53. In other words, FIG. 12 shows part of a cross section of the projector 1 taken along an XZ plane.

The second duct 53 is a duct through which the first fan 51 exhausts the air, and couples the sending portion 513 of the first fan 51 to the discharge ports 241. The second duct 53 is so provided that the cooling gas can flow between the sending portion 513 and the discharge ports 241, and constitutes the second flow path, at least part of which is formed by the second surface 412 different from the first surface 411 in the wireless communication apparatus 4. In detail, part of the second surface 412 is exposed to the interior of the second duct 53, and the second heat dissipation member 317 is disposed in the second duct 53. That is, in the second flow path, which is formed by the second duct 53 and through which the cooling gas flows, the second heat dissipation member 317 is provided downstream from the position where the cooling gas cools the wireless communication apparatus 4. The wireless communication apparatus 4 corresponds to the first cooling target, and the second heat dissipation member 317 corresponds to the second cooling target. The amount of heat generated by the second heat dissipation member 317 is greater than the amount of heat generated by the wireless communication apparatus 4.

The second duct 53 is formed of a duct member including a first sub-duct 531 and a second sub-duct 532.

### Configuration of First Sub-Duct

The first sub-duct 531 constitutes a first sub-flow path through which the cooling gas sent from the sending portion 513 of the first fan 51 toward the negative end of the X direction flows to the second surface 412 and the second heat dissipation member 317. The first sub-duct 531 includes a first opening 5311, an inclining part 5312, and a second opening 5313.

The first opening 5311 of the first sub-duct 531 opens toward the negative end of the Z direction. The first opening 5311 is closed by the second surface 412 of the wireless communication apparatus 4 disposed at a position shifted from the first sub-duct 531 toward the negative end of the Z direction. Part of the second surface 412 is therefore exposed to the interior of the first sub-duct 531 via the first opening 5311.

The inclining part 5312 constitutes the inner surface of the first sub-duct 531. The inclining part 5312 inclines in such a way that the inclining part 5312 extends toward the positive end of the Z direction as extending from the end thereof facing the negative end of the X direction at the first opening 5311 toward the negative end of the X direction. The inclining part 5312 guides the cooling gas having flowed along the second surface 412, which is exposed to the interior of the first opening 5311, to the second heat dissipation member 317.

The second opening 5313 is an opening through which the second heat dissipation member 317, which protrudes from the light source housing CA toward the negative end of the Z direction, is inserted toward the negative end of the Z direction. The second heat dissipation member 317 inserted through the second opening 5313 is disposed in the first sub-duct 531.

The thus configured first sub-duct 531 linearly extends along the X direction toward the negative end thereof, which is the direction in which the cooling gas from the sending portion 513 of the first fan 51 is sent. That is, the first sub-flow path in the first sub-duct 531 linearly extends over the range from the sending portion 513 to the second heat dissipation member 317.

### Configuration of Second Sub-Duct

The second sub-duct 532 constitutes a second sub-flow path that guides the cooling gas having flowed along the second heat dissipation member 317 to the discharge ports 241.

The discharge ports 241 are disposed at positions shifted from an imaginary line VL, which connects the sending portion 513 of the first fan 51 to the second heat dissipation member 317. In detail, the discharge ports 241 are shifted from the imaginary line VL toward the positive end of the Z direction. The second sub-duct 532 therefore intersects with the first sub-duct 531, which extends along the X-axis, and extends from the portion where the second sub-duct 532 is coupled to the first sub-duct 531 toward the positive end of the Z direction. The second sub-duct 532 includes a guide part 5321.

The guide part 5321 is provided at a position where the guide part 5321 opposes the discharge ports 241 in the second sub-duct 532. The guide part 5321 inclines so as to extend toward the negative end of the X direction or approach the discharge ports 241 as extending toward the positive end of the Z direction. The guide part 5321 changes the flow direction of the cooling gas having flowed through the second sub-duct 532 toward the positive end of the Z direction to the X direction toward the negative end thereof or toward the discharge ports 241. The thus configured guide part 5321 causes the cooling gas having flowed through the second sub-duct 532 to be quickly discharged via the discharge ports 241.

### Flow of Cooling Gas Flowing Through Second Duct

Out of a cooling gas FW3 sent from the sending portion 513 of the first fan 51 into the first sub-duct 531 of the second duct 53, a cooling gas FW31 sent from the portion of the sending portion 513 that faces the negative end of the Z direction flows along the second surface 412 of the wireless communication apparatus 4, which is exposed to the first opening 5311. A portion of the wireless communication apparatus 4 that faces the second surface 412 is thus cooled.

The cooling gas FW31 having flowed along the second surface 412 flows along the inclining part 5312 toward the negative end of the X direction and the positive end of the Z direction, and flows to the second heat dissipation member 317 along with other cooling gases FW32 and FW33 sent from the sending portion 513. The second heat dissipation member 317 is thus cooled, and the wavelength converter 316 is in turn cooled.

A cooling gas FW4 having flowed through the second heat dissipation member 317 flows through the second sub-duct 532 toward the positive end of the Z direction. The cooling gas having flowed toward the positive end of the Z direction is caused by the guide portion 5321 to flow toward the negative end of the X direction, and is discharged out of the exterior housing 2 via the discharge ports 241.

### Effects of Embodiment

The projector 1 according to the present embodiment described above provides the effects below.

The projector 1 projects image light. The projector 1 includes the exterior housing 2, the wireless communication apparatus 4, the first fan 51, the first duct 52, and the second duct 53.

The exterior housing 2 has the rear surface 22, the first intake ports 264, the communication ports 2CA1, and the discharge ports 241. The first intake ports 264 and the communication ports 2CA1 are the introduction ports via which the air outside the exterior housing 2 is introduced as the cooling gas into the exterior housing 2. The discharge ports 241 discharge the cooling gas having flowed through the interior of the exterior housing 2.

The wireless communication apparatus 4 corresponds to the first cooling target. The wireless communication apparatus 4 is disposed inside the exterior housing 2 along the inner side of the rear surface 22.

The first fan 51 corresponds to a cooling fan, and is provided inside the exterior housing 2. The first fan 51 includes the intake portions 511 and 512, which suck the cooling gas, and the sending portion 513, which sends the sucked cooling gas.

The first duct 52 constitutes the first flow path. The first flow path is so formed that the cooling gas can flow between at least one of the introduction ports, the first intake ports 264 or the communication ports 2CA1, and the intake portions 511 and 512. The first flow path is formed at least partially by the first surface 411 of the wireless communication apparatus 4.

The second duct 53 constitutes the second flow path. The second flow path is so formed that the cooling gas can flow between the sending portion 513 and the discharge ports 241. The second flow path is formed at least partially by the second surface 412 different from the first surface 411 in the wireless communication apparatus 4.

According to the configuration described above, the cooling gas is allowed to flow to each of the first surface 411 and the second surface 412 different from the first surface 411 in the wireless communication apparatus 4. The wireless communication apparatus 4 can therefore be cooled by the cooling gas flowing to each of the first surface 411 and the second surface 412, so that the efficiency at which the wireless communication apparatus 4 is cooled can be increased. The wireless communication apparatus 4 can therefore be effectively cooled, so that an increase in the size of the projector can be suppressed, and an increase in power consumption, an increase in the amount of heat generated by the power supply system, and an increase in the noise generated by the cooling fan, all of which are associated with an increase in the rotational speed of the cooling fan, can be suppressed.

In the projector 1, the inner side of the rear surface 22 opposes the first surface 411, which constitutes the first flow path.

According to the configuration described above, the first flow path is formed between the inner side of the rear surface 22 and the first surface 411 in the wireless communication apparatus 4, so that an increase in the size of the projector 1 can be suppressed.

In the projector 1, the inner side of the rear surface 22 opposes the first surface 411, which constitutes the first flow path. The exterior housing 2 has the bottom surface 26, which is continuous with the rear surface 22 and intersects with the rear surface 22. The first intake ports 264, which are at least part of the introduction ports, are provided at the bottom surface 26.

According to the configuration described above, the cooling gas having flowed along the inner side of the rear surface 22 is readily allowed to flow to the first surface 411, which opposes the inner side of the rear surface 22 in the wireless communication apparatus 4 disposed along the rear surface 22. The efficiency at which the wireless communication apparatus 4 is cooled can therefore be increased.

The projector 1 includes the second heat dissipation member 317 provided downstream from the position where the cooling gas cools the wireless communication apparatus 4 in the second flow path. The second heat dissipation member 317 corresponds to the second cooling target.

According to the configuration described above, the common first fan 51 can cool not only the wireless communication apparatus 4 but also the second heat dissipation member 317. Therefore, the complication of the configuration of the projector 1 can be suppressed, and an increase in the size of the projector 1 can be suppressed, as compared with a case where a cooling fan that cools the second heat dissipation member 317 is provided separately from a cooling fan that cools the wireless communication apparatus 4.

In the projector 1, the amount of heat generated by the second heat dissipation member 317 is greater than the amount of heat generated by the wireless communication apparatus 4.

According to the configuration described above, the wireless communication apparatus 4, which generates a small amount of heat, is cooled by the cooling gas sent by the first fan 51 earlier than the second heat dissipation member 317. The cooling gas having a relatively low temperature is thus allowed to flow also to the second heat dissipation member 317. The wireless communication apparatus 4 and the second heat dissipation member 317, which generate different amounts of heat, can therefore be efficiently cooled.

In the projector 1, the first cooling target is the wireless communication apparatus 4.

According to the configuration described above, the wireless communication apparatus 4 can be efficiently cooled.

The projector 1 includes the light source apparatus 31, which outputs light, and the second heat dissipation member 317, which dissipates the heat of the wavelength converter 316 of the light source apparatus 31. The second cooling target is the second heat dissipation member 317.

According to the configuration described above, the second heat dissipation member 317 can be efficiently cooled, and the light source apparatus 31 can in turn be efficiently cooled.

In the projector 1, the second surface 412 of the wireless communication apparatus 4 is provided at the side opposite from the first surface 411 with respect to the wireless communication apparatus 4. The first fan 51 is oriented with respect to the wireless communication apparatus 4 in the direction from the first surface 411 toward the second surface 412. In the second flow path, the flow path over the range from the sending portion 513 to the second heat dissipation member 317 linearly extends.

In the configuration in which the cooling gas sent from the first fan 51 flows to the first surface 411 and the second surface 412 of the wireless communication apparatus 4 and then flows to the second heat dissipation member 317, the first fan 51, the wireless communication apparatus 4, and the second heat dissipation member 317 are arranged side by side in the direction in which the cooling gas is sent from the first fan 51. In the configuration described above, the dimension of the projector 1 in the cooling gas sending direction increases, so that reduction in the size of the projector 1 is inhibited.

In the configuration in which the first fan 51 sucks the cooling gas having flowed along the first surface 411 and the second surface 412 of the wireless communication apparatus 4, and the cooling gas sent by the first fan 51 flows to the second heat dissipation member 317, it is necessary to provide a gap along the Z-axis through which the cooling gas flows to each of the first surface 411 and the second surface 412. In the configuration described above, when the wireless communication apparatus 4 and the second heat dissipation member 317 are arranged in the direction perpendicular to the cooling gas sending direction, the dimension of the projector 1 in the cooling gas sending direction becomes smaller, but the dimension of the projector 1 in the direction perpendicular to the cooling gas sending direction becomes greater. On the other hand, when the wireless communication apparatus 4 and the second heat dissipation member 317 are separated from each other along the cooling gas sending direction described above so that the wireless communication apparatus 4 and the second heat dissipation member 317 do not overlap each other when viewed along the direction perpendicular to the cooling gas sending direction, the dimension of the projector 1 in the direction perpendicular to the cooling gas sending direction decreases depending on the flow path width of the second flow path, but the dimension of the projector 1 in the cooling gas sending direction described above increases.

In contrast, the cooling gas sucked by the first fan 51 flows along the first surface 411 of the wireless communication apparatus 4, and the cooling gas sent from the first fan 51 flows through the linearly extending second flow path, flows along the second surface 412 of the wireless communication apparatus 4, and then flows to the second heat dissipation member 317. The configuration described above eliminates the need to provide the gap through which the cooling gas sucked by the first fan 51 flows along the second surface 412. An increase in the dimension of the projector 1 along the Z-axis can therefore be suppressed, so that an increase in the size of the projector 1 can be suppressed.

The projector 1 includes the image formation unit 35, which forms image light. The image formation unit 35 includes the light modulators 352, which modulate the light incident thereon. The wireless communication apparatus 4 is disposed on the side opposite from the image formation unit 35 with respect to the first fan 51 and the second flow path of the second duct 53.

The image formation unit 35 forms a heat source when blocking the light incident thereon.

In contrast, the first fan 51 and the second flow path are disposed between the wireless communication apparatus 4 and the image formation unit 35, so that the wireless communication apparatus 4 is thermally isolated from the image formation unit 35 by the first fan 51 and the second flow path. The influence of the heat of the image formation unit 35 on the wireless communication apparatus 4 can therefore be suppressed.

In the projector 1, the discharge ports 241 are provided at positions separate from the imaginary line VL extending from the sending portion 513 toward the second heat dissipation member 317. The second flow path formed by the second duct 53 includes the first sub-flow path and the second sub-flow path.

The first sub-flow path is formed by the first sub-duct 531. The first sub-flow path is a flow path over the range from the sending portion 513 to the second heat dissipation member 317.

The second sub-flow path is formed by the second sub-duct 532. The second sub-flow path is a flow path that intersects with the first sub-flow path and extends over the range from the second heat dissipation member 317 to the discharge ports 241.

According to the configuration described above, even when the discharge ports 241 are provided at positions separate from the imaginary line VL described above, the configuration in which the second flow path includes the second sub-flow path allows the cooling gas having flowed through the second flow path to be discharged out of the exterior housing 2 via the discharge ports 241. The flexibility of the layout of the discharge ports 241 in the exterior housing 2 can therefore be increased.

### Variations of Embodiments

The present disclosure is not limited to the embodiment described above, and variations, improvements, and other modifications to the extent that the advantage of the present disclosure is achieved fall within the scope of the present disclosure.

In the embodiment described above, the first cooling target is the wireless communication apparatus 4, and the second cooling target is the second heat dissipation member 317, which dissipates the heat of the wavelength converter 316, but not necessarily. The first cooling target having the configuration in which the first fan 51 causes the cooling gas to flow to the first surface and the second surface different from the first surface may be another member or apparatus. The second cooling target may, for example, be the first heat dissipation member 312, which dissipates the heat from the light source 311, or may be another member or apparatus. Furthermore, the second cooling target may not be provided downstream from the position where the cooling gas cools the first cooling target.

It is assumed in the embodiment described above that the first duct 52, which constitutes the first flow path, is formed by the inner side of the rear surface 22, the speaker housing 61 of the speaker unit 6, and the first surface 411 of the wireless communication apparatus 4, but not necessarily. The first duct 52 may be formed by a duct member that couples at least one of the first intake ports 264 and the communication ports 2CA1 to the intake portion 511 of the first fan 51, and the first surface 411 of the wireless communication apparatus 4. That is, the first duct 52 may be formed by a member or an apparatus other than the speaker unit 6.

It is assumed in the embodiment described above that in the wireless communication apparatus 4, which is the first cooling target, the first surface 411, which constitutes the first flow path, is a surface facing the negative end of the Z direction, and the second surface 412, which constitutes the second flow path, is a surface facing the positive end of the Z direction, but not necessarily. The first surface and the second surface may each be a surface of the housing 41 of the wireless communication apparatus 4 that is oriented in another direction as long as the first surface and the second surface are surfaces different from each other. For example, the first surface may be a surface facing the negative end of the Z direction, and the second surface may be a surface facing the negative end of the Y direction.

It is assumed in the embodiment described above that the outside air sucked by the first fan 51 is a gas that flows through at least one of the first intake ports 264 and the communication ports 2CA1 and is introduced into the exterior housing 2. That is, it is assumed that t the introduction ports in the present disclosure are the first intake ports 264 and the communication ports 2CA1. However, the configuration described above is not necessarily employed, and one of the first intake ports 264 and the communication ports 2CA1 may be omitted. Furthermore, the introduction ports in the present disclosure may be provided at an outer surface having an inner side different from the inner side that opposes the first surface of the first cooling target. For example, the introduction ports may be provided at any one of the right side surface 23, the left side surface 24, and the top surface 25.

It is assumed in the embodiment described above that the amount of heat generated by the second heat dissipation member 317 is greater than the amount of heat generated by the wireless communication apparatus 4. That is, in the second flow path, the amount of heat generated by the downstream second cooling target is greater than the amount of heat generated by the upstream first cooling target. However, the configuration described above is not necessarily employed, and the amount of heat generated by the second cooling target may be smaller than the amount of heat generated by the first cooling target or may be equal to the amount of heat generated by the first cooling target.

It is assumed in the embodiment described above that the first sub-duct 531 of the second duct 53 is formed linearly, and that the first sub-flow path that is part of the second flow path and formed by the first sub-duct 531 path extends linearly, but not necessarily. The first sub-flow path may not necessarily be linear as long as the cooling gas flows to the second surface of the first cooling target and the cooling gas having flowed to the second surface flows to the second cooling target.

It is assumed in the embodiment described above that the wireless communication apparatus 4 is disposed on the side opposite from the image formation unit 35 with respect to the first fan 51 and the second duct 53. In detail, it is assumed that the wireless communication apparatus 4 is disposed on the side opposite from the image formation unit 35 with respect to the first fan 51, the second duct 53, and the color separation system 33. That is, it is assumed that the first fan 51, the second duct 53, and the color separation system 33 are disposed between the wireless communication apparatus 4 and the image formation unit 35. The positional relationship between the wireless communication apparatus 4, which is the first cooling target, and the image formation unit 35 is, however, not limited to the positional relationship described above. For example, the wireless communication apparatus 4 and the image formation unit 35 may be disposed at positions adjacent to each other.

It is assumed in the embodiment described above that the discharge ports 241, via which the cooling gas having flowed through the second flow path is discharged, are provided at positions separate from the imaginary line VL, which extends from the sending portion 513 of the first fan 51 toward the second heat dissipation member 317, but not necessarily. The discharge ports 241 may be provided on the imaginary line VL, which extends from the sending portion 513 of the first fan 51 toward the second heat dissipation member 317. Still instead, the discharge ports 241 are not necessarily provided at the left side surface 24, and may be provided at another surface, for example, the top surface 25.

It is assumed in the embodiment described above that the projector 1 includes the three light modulators 352R, 352G, and 352B, but not necessarily. The contents of the present disclosure are also applicable to a projector including two or fewer or four or greater number of light modulators.

In the embodiment described above, the image projection apparatus 3 is formed in a substantially L shape when viewed from the side facing the positive end of the Y direction, as shown in FIG. 4, but not necessarily. The configuration and the layout of the image projection apparatus 3 are not limited to those described above, and the image projection apparatus 3 may be formed, for example, in a substantially U shape.

It is assumed in the embodiment described above that the light modulators 352 each include a transmissive liquid crystal panel having a light incident surface and a light exiting surface different from each other, but not necessarily. The light modulators may each be a reflective liquid crystal panel having a surface that serves both as the light incident surface and the light exiting surface. Furthermore, a light modulator using component other than any a liquid-crystal-based component, such as a device using micromirrors, for example, a digital micromirror device (DMD), may be employed as long as the component is capable of modulating an incident luminous flux to form an image according to image information.

### Summary of Present Disclosure

The present disclosure will be summarized below as additional remarks.

### Additional Remark 1

A projector that projects image light, the projector including
an exterior housing having a first wall, an introduction port via which outside air is introduced as a cooling gas into the exterior housing, and a discharge port via which the cooling gas flowed through the interior of the exterior housing is discharged,
a first cooling target disposed inside the exterior housing along the inner surface of the first wall,
a cooling fan provided inside the exterior housing and including an intake portion that sucks the cooling gas and a sending portion that sends the sucked cooling gas,
a first flow path so formed that the cooling gas is allowed to flow between the introduction port and the intake portion and at least part of the first flow path is formed by a first surface of the first cooling target, and
a second flow path so formed that the cooling gas is allowed to flow between the sending portion and the discharge port and at least part of the second flow path is formed by a second surface different from the first surface in the first cooling target.

According to the configuration described above, the cooling gas is allowed to flow to each of the first surface of the first cooling target and the second surface thereof different from the first surface. The first cooling target can therefore be cooled by the cooling gas flowing to each of the first and second surfaces, so that the efficiency at which the first cooling target is cooled can be increased. The first cooling target can therefore be effectively cooled, so that an increase in the size of the projector can be suppressed, and an increase in power consumption, an increase in the amount of heat generated by the power supply system, and an increase in the noise generated by the cooling fan, all of which are associated with an increase in the rotational speed of the cooling fan, can be suppressed.

### Additional Remark 2

The projector described in the additional remark 1, in which
the inner surface of the first wall opposes the first surface, which constitutes the first flow path.

According to the configuration described above, the first flow path is formed between the inner surface of the first wall and the first surface of the first cooling target, so that an increase in the size of the projector can be suppressed.

### Additional Remark 3

The projector described in the additional remark 1 or 2, in which
the inner surface of the first wall opposes the first surface, which constitutes the first flow path,
the exterior housing has a second wall that is continuous with the first wall and intersects with the first wall, and
at least part of the introduction port is provided at the second wall.

According to the configuration described above, the cooling gas having flowed along the inner surface of the first wall is readily allowed to flow to the first surface, which opposes the inner surface of the first wall in the first cooling target disposed along the first wall. The efficiency at which the first cooling target is cooled can therefore be increased.

### Additional Remark 4

The projector described in any one of the additional remarks 1 to 3, further including
a second cooling target provided downstream from the position where the cooling gas cools the first cooling target in the second flow path.

According to the configuration described above, the common cooling fan can cool not only the first cooling target but also the second cooling target. Therefore, the complication of the configuration of the projector can be suppressed, and an increase in the size of the projector can be suppressed, as compared with a case where a cooling fan that cools the second cooling target is provided separately from a cooling fan that cools the first cooling target.

### Additional Remark 5

The projector described in the additional remark 4, in which
the amount of heat generated by the second cooling target is greater than the amount of heat generated by the first cooling target.

According to the configuration described above, the first cooling target, which generates a small amount of heat, is cooled by the cooling gas sent by the cooling fan earlier than the second cooling target. The cooling gas having a relatively low temperature is thus allowed to flow also to the second cooling target. The first and second cooling targets, which generate different amounts of heat, can therefore be efficiently cooled.

### Additional Remark 6

The projector described in the additional remark 5, in which
the first cooling target is a wireless communication apparatus.

According to the configuration described above, the wireless communication apparatus can be efficiently cooled.

### Additional Remark 7

The projector described in the additional remark 5 or 6, further including
a light source apparatus that outputs light, and
a heat dissipation member to which heat of the light source apparatus is transferred, in which
the second cooling target is the heat dissipation member.

According to the configuration described above, the heat dissipation member can be efficiently cooled, and the light source apparatus can in turn be efficiently cooled.

### Additional Remark 8

The projector described in any one of the additional remarks 4 to 7, in which
the second surface is provided at the side opposite from the first surface with respect to the first cooling target,
the cooling fan is oriented with respect to the first cooling target in the direction from the first surface toward the second surface, and
the flow path over the range from the sending portion to the second cooling target in the second flow path extends linearly.

In the configuration in which the cooling gas sent from the cooling fan flows to the first surface and the second surface of the first cooling target and then flows to the second cooling target, the cooling fan, the first cooling target, and the second cooling target are arranged side by side in the direction in which the cooling fan sends the cooling gas. In the configuration described above, the dimension of the projector in the cooling gas sending direction increases, so that reduction in the size of the projector is inhibited.

In the configuration in which the cooling fan sucks the cooling gas having flowed along the first surface and the second surface of the first cooling target, and the cooling gas sent by the cooling fan flows to the second cooling target, it is necessary to provide a gap through which the cooling gas flows to each of the first surface and the second surface. In the configuration described above, when the first cooling target and the second cooling target are arranged in the direction perpendicular to the cooling gas sending direction described above, the dimension of the projector in the cooling gas sending direction becomes smaller, but the dimension of the projector in the direction perpendicular to the cooling gas sending direction becomes greater. On the other hand, when the first cooling target and the second cooling target are separated from each other along the cooling gas sending direction described above so that the first cooling target and the second cooling target do not overlap each other when viewed along the direction perpendicular to the cooling gas sending direction, the dimension of the projector in the direction perpendicular to the cooling gas sending direction decreases depending on the flow path width of the second flow path, but the dimension of the projector in the cooling gas sending direction described above increases.

In contrast, according to the configuration described above, the cooling gas sucked by the cooling fan flows along the first surface of the first cooling target, and the cooling gas sent from the cooling fan flows through the linearly extending second flow path, flows along the second surface of the first cooling target, and then flows to the second cooling target. The configuration described above eliminates the need to provide the gap through which the cooling gas sucked by the cooling fan flows along the second surface. An increase in the dimension of the projector in the aforementioned direction perpendicular to the cooling gas sending direction can therefore be suppressed, so that an increase in the size of the projector can be suppressed.

### Additional Remark 9

The projector described in the additional remark 8, further including
an image formation unit including a light modulator that modulates light incident thereon and forms the image light, in which
the first cooling target is disposed at the side opposite from the image formation unit with respect to the cooling fan and the second flow path.

The image formation unit forms a heat source when blocking the light incident thereon.

In contrast, the cooling fan and the second flow path are disposed between the first cooling target and the image formation unit, so that the first cooling target is thermally isolated from the image formation unit by the cooling fan and the second flow path. The influence of the heat of the image formation unit on the first cooling target can therefore be suppressed.

### Additional Remark 10

The projector described in the additional remark 8 or 9, in which
the discharge port is provided at a position separate from an imaginary line extending from the sending portion toward the second cooling target, and
the second flow path includes
a first sub-flow path extending over the range from the sending portion to the second cooling target, and
a second sub-flow path that intersects with the first sub-flow path and extends over the range from the second cooling target to the discharge port.

According to the configuration described above, even when the discharge port is provided at a position separate from the imaginary line, the configuration in which the second flow path includes the second sub-flow path allows the cooling gas having flowed through the second flow path to be discharged out of the exterior housing via the discharge port. The flexibility of the layout of the discharge port in the exterior housing can therefore be increased.

What is claimed is:

1. A projector that projects image light, the projector comprising:
an exterior housing having a first wall, an introduction port via which outside air is introduced as a cooling gas into the exterior housing, and a discharge port via which the cooling gas flowed through the interior of the exterior housing is discharged;
a first cooling target disposed inside the exterior housing along an inner surface of the first wall;
a cooling fan provided inside the exterior housing and including an intake portion that sucks the cooling gas and a sending portion that sends the sucked cooling gas;
a first flow path that cause the cooling gas to flow between the introduction port and the intake portion, at least part of the first flow path being formed by a first surface of the first cooling target; and
a second flow path that cause the cooling gas to flow between the sending portion and the discharge port, at least part of the second flow path being formed by a second surface different from the first surface in the first cooling target.

2. The projector according to claim 1, wherein
the inner surface of the first wall opposes the first surface, which constitutes the first flow path.

3. The projector according to claim 1, wherein
the inner surface of the first wall opposes the first surface, which constitutes the first flow path,
the exterior housing has a second wall that is continuous with the first wall and intersects with the first wall, and
at least part of the introduction port is provided at the second wall.

4. The projector according to claim 1, further comprising
a second cooling target provided downstream from a position where the cooling gas cools the first cooling target in the second flow path.

5. The projector according to claim 4, wherein
an amount of heat generated by the second cooling target is greater than an amount of heat generated by the first cooling target.

6. The projector according to claim 5, wherein
the first cooling target is a wireless communication apparatus.

7. The projector according to claim 5, further comprising:
a light source apparatus that outputs light; and
a heat dissipation member to which heat of the light source apparatus is transferred,
wherein the second cooling target is the heat dissipation member.

8. The projector according to claim 4, wherein
the second surface is provided at a side opposite from the first surface with respect to the first cooling target,
the cooling fan is oriented with respect to the first cooling target in a direction from the first surface toward the second surface, and
a flow path over a range from the sending portion to the second cooling target in the second flow path extends linearly.

9. The projector according to claim 8, further comprising
an image formation unit including a light modulator that modulates light incident thereon and forms the image light,
wherein the first cooling target is disposed at a side opposite from the image formation unit with respect to the cooling fan and the second flow path.

10. The projector according to claim 8, wherein
the discharge port is provided at a position shifted from an imaginary line extending from the sending portion toward the second cooling target, and
the second flow path includes
a first sub-flow path extending over the range from the sending portion to the second cooling target, and
a second sub-flow path that intersects with the first sub-flow path and extends over a range from the second cooling target to the discharge port.
